(19) United States
(12) Patent Application Publication
(10) Pub. No.: US 2025/0391706 A1
(43) Pub. Date: Dec. 25, 2025

(54) DEVICE CHIP PRODUCTION METHOD AND LASER PROCESSING APPARATUS

(71) Applicant: DISCO CORPORATION, Tokyo (JP)

(72) Inventors: Kei TANAKA, Tokyo (JP); Yuta MIZUMOTO, Tokyo (JP)

(21) Appl. No.: 19/240,078

(22) Filed: Jun. 17, 2025

(30) Foreign Application Priority Data
Jun. 21, 2024 (JP) 2024-100307

(51) Int. Cl. H01L 21/78; H01L 21/268; H01L 21/67

(52) U.S. Cl. CPC H01L 21/78; H01L 21/268; H01L 21/67092

(57) ABSTRACT

A method includes: a first processing step of forming a modified layer inside a workpiece by irradiating the workpiece with a laser beam having a wavelength that transmits through the workpiece along a first planned dividing line; a second processing step of forming a modified layer inside the workpiece by irradiating the workpiece with the laser beam along an adjacent planned dividing line adjacent to the first planned dividing line; and a position coordinate acquisition step of acquiring a position coordinate of a key pattern formed in a predetermined region of the workpiece along an extending direction of the adjacent planned dividing line, after the first processing step is performed, and in the second processing step, the adjacent planned dividing line is corrected based on the position coordinate of the key pattern, and the workpiece is irradiated with the laser beam along the corrected adjacent planned dividing line.

### CROSS-REFERENCE TO RELATED APPLICATIONS

This application is based on and claims priority under 35 USC 119 from Japanese Patent Application No. 2024-100307 filed on Jun. 21, 2024, the contents of which are incorporated herein by reference.

### TECHNICAL FIELD

The present disclosure relates to a device chip production method and a laser processing apparatus.

### BACKGROUND ART

As a method for producing a device chip by dividing a plate-shaped workpiece such as a semiconductor wafer, there is known a method for producing a device chip by irradiating the inside of the workpiece with a laser beam that is transparent to the workpiece to form a modified layer and applying an external force to the workpiece with the modified layer as a starting point to divide the workpiece (for example, Patent Literature 1).
Patent Literature 1: JP3408805B

### SUMMARY

In the device chip production method described in Patent Literature 1, a street formed in the workpiece is defined as a planned dividing line, and the modified layer is formed along the planned dividing line. When the modified layer is formed, the mechanical strength of regions surrounding the modified layer may decrease, causing the workpiece to expand in a direction perpendicular to the direction in which the street extend, resulting in deformation such as curvature of the street to be processed. When such a curved street defined as the planned dividing line is linearly irradiated with the laser beam, a device and the like may be irradiated with the laser beam, which not only leads to damage to a product, but also may cause defective division and the like as no appropriate modified layers are formed inside a wafer, which is the workpiece.

The present disclosure provides a device chip production method and a laser processing apparatus capable of reducing damage to devices and defective division of workpieces even when streets are deformed.

According to an aspect of the present disclosure, there is provided a device chip production method for producing a device chip by dividing a workpiece in which a plurality of devices are formed in regions partitioned by a plurality of planned dividing lines along the planned dividing lines, the method including:
a first processing step of forming a modified layer inside the workpiece by irradiating the workpiece with a laser beam having a wavelength that transmits through the workpiece along a first planned dividing line;
a second processing step of forming a modified layer inside the workpiece by irradiating the workpiece with the laser beam along an adjacent planned dividing line adjacent to the first planned dividing line processed in the first processing step, after the first processing step is performed; and
a position coordinate acquisition step of acquiring a position coordinate of a key pattern formed in a predetermined region of the workpiece along an extending direction of the adjacent planned dividing line, after the first processing step is performed, in which
in the second processing step, the adjacent planned dividing line is corrected based on the position coordinate of the key pattern acquired in the position coordinate acquisition step, and the workpiece is irradiated with the laser beam along the corrected adjacent planned dividing line.

According to another aspect of the present disclosure, there is provided a laser processing apparatus for processing a workpiece having a plurality of devices formed in regions partitioned by a plurality of planned dividing lines by irradiating the workpiece with a laser beam, the laser processing apparatus including:
a holding table configured to hold the workpiece;
a laser irradiation unit configured to irradiate the workpiece with the laser beam having a wavelength that is transparent to the workpiece to form a modified layer inside the workpiece;
a moving unit configured to relatively move the workpiece held on the holding table and a focal point of the laser beam;
an acquisition unit configured to acquire a position coordinate of a key pattern formed in a predetermined region of the workpiece; and
a control unit configured to control the laser processing apparatus, in which
the control unit includes
   a position coordinate acquisition unit configured to acquire the position coordinate of the key pattern acquired by the acquisition unit, and
   an irradiation position correction unit configured to correct the planned dividing line based on the acquired position coordinate and irradiate the workpiece with the laser beam along the corrected planned dividing line.

### BRIEF DESCRIPTION OF DRAWINGS

FIG. 1 is a perspective view illustrating an example of a laser processing apparatus 1.

FIG. 2 is a perspective view illustrating an example of a workpiece 10.

FIG. 3 is a top view illustrating an example of the workpiece 10.

FIG. 4 is a diagram for explaining an example of a configuration of a control unit 100.

FIG. 5 is a flowchart illustrating an example of a process of a device chip production method.

FIG. 6 is a diagram for explaining an image of a key pattern P acquired in a position coordinate acquisition step S11.

FIG. 7 is a diagram for explaining a planned dividing line Lc corrected in a second processing step S12.

FIG. 8 is a diagram for explaining a process in the second processing step S12, and in particular, a diagram illustrating an example in which the position coordinate acquisition step S11 and the second processing step S12 are performed in parallel.

FIG. 9 is a diagram for explaining a modification of the position coordinate acquisition step S11.

FIG. 10 is a diagram for explaining a modification of a laser irradiation unit 30 an imaging unit 50.

### DESCRIPTION OF EMBODIMENTS

Hereinafter, a device chip production method and a laser processing apparatus 1 according to an embodiment of the present disclosure will be described with reference to the drawings.

First, before describing the details of the device chip production method, a configuration of the laser processing apparatus 1 used for producing a device chip will be described.

In the following description, an X-axis direction is a direction on a horizontal plane. A Y-axis direction is a direction orthogonal to the X-axis direction on the horizontal plane. AZ-axis direction is a direction orthogonal to the X-axis direction and the Y-axis direction.

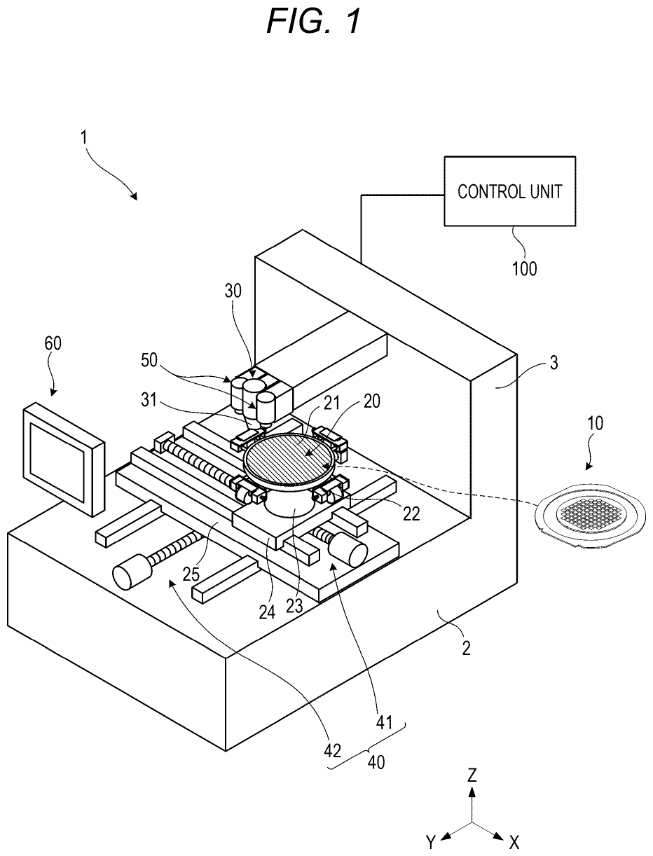

FIG. 1 is a perspective view illustrating an example of the laser processing apparatus 1 according to an embodiment. The laser processing apparatus 1 processes a workpiece 10 by irradiating the workpiece 10, which is an object to be processed, with a laser beam. The processing of the workpiece 10 by the laser processing apparatus 1 is, for example, modified layer forming processing of forming a modified layer inside the workpiece 10 by a laser beam. Here, the workpiece 10 will be described.

### (Workpiece)

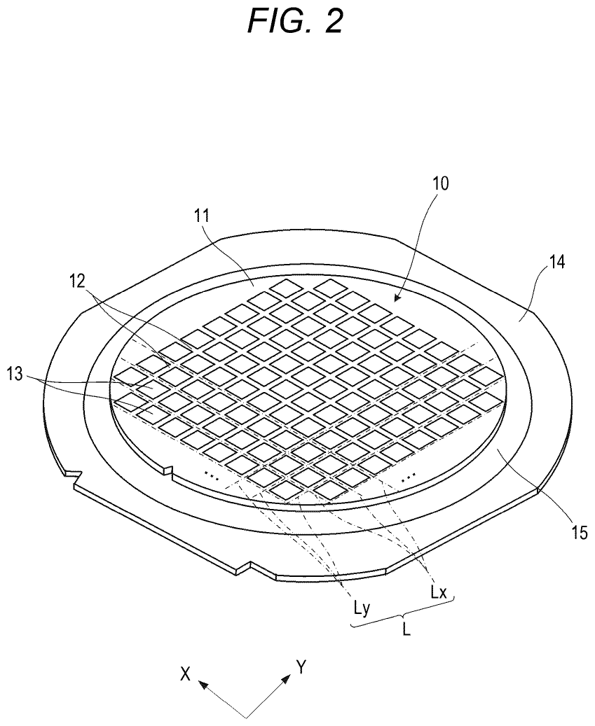

The workpiece 10 is, for example, a substantially disk-shaped wafer or optical device wafer made of silicon (Si), silicon carbide (SiC), gallium nitride (GaN), gallium arsenide (GaAs), or other semiconductors materials. The workpiece 10 may be various plate-shaped processing materials such as a plate-shaped inorganic material substrate of ceramics, glass, or sapphire, or a plate-shaped ductile material such as metal or resin. The workpiece 10 may be a package substrate or the like including a plurality of device chips sealed with mold resin or the like. FIG. 2 illustrates a wafer as an example of the workpiece 10.

As illustrated in FIG. 2, on a front surface 11 of the workpiece 10, a plurality of streets 12 intersecting each other are defined as planned dividing lines L, and a plurality of regions partitioned by the planned dividing lines L are formed in a grid pattern. A device 13 such as an integrated circuit (IC), a large scale integrated circuit (LSI), or a micro electro mechanical system (MEMS) is formed in each of the regions partitioned by the planned dividing lines L. The planned dividing lines L include planned dividing lines Lx extending in one direction (for example, the X-axis direction) and planned dividing lines Ly extending in the other direction (for example, the Y-axis direction) intersecting the one direction. In the example illustrated in FIG. 2, three planned dividing lines Lx and three planned dividing lines Ly are representatively denoted by reference numerals, and each is indicated by a dashed dotted line. When the wafer, which is the workpiece 10, is divided along the planned dividing lines L, individual device chips are formed. In the embodiment, each of the device chips has, for example, a square shape, but may have a rectangular shape.

In the embodiment, the reference numeral “Lx” is used when indicating planned dividing lines extending in the X-axis direction, the reference numeral “Ly” is used when indicating planned dividing lines extending in the Y-axis direction, and the reference numeral “L” is simply used when the planned dividing lines extending in the X-axis direction and the planned dividing lines extending in the Y-axis direction are not distinguished from each other. As will be described later, for example, when the plurality of planned dividing lines extending in the X-axis direction are distinguished from each other, reference numerals “Lx₁”, “Lx₂” and the like obtained by adding numbers to “Lx” are used.

The workpiece 10 is conveyed and processed in a state where the workpiece 10 is integrated with an annular frame 14 and a tape 15 attached so as to close an opening of the annular frame 14. The frame 14 is an annular plate member made of, for example, metal or resin and having an opening larger than an outer diameter of the workpiece 10. The tape 15 has expandability and has a sheet shape having an outer diameter larger than the opening of the frame 14. The tape 15 is attached to a back surface of the frame 14 so as to cover the opening of the frame 14. The workpiece 10 is positioned at a predetermined position in the opening of the frame 14, and a back surface of the workpiece 10 is attached to the tape 15, whereby the workpiece 10 is fixed to the frame 14 and the tape 15.

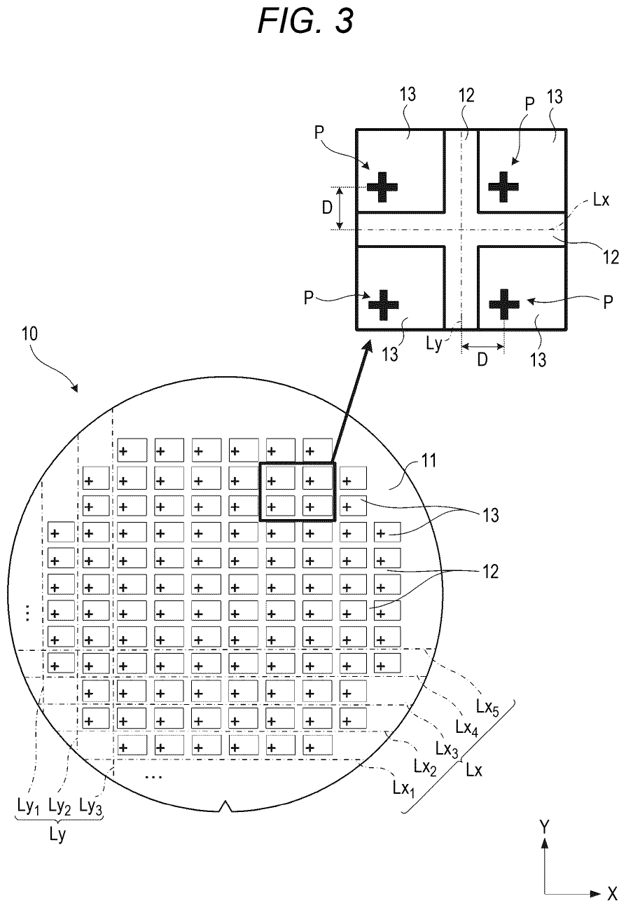

As illustrated in FIG. 3, characteristic key patterns P are formed in predetermined regions (for example, a part enlarged illustrated in FIG. 3) on the front surface 11 of the workpiece 10. Each of the key patterns P is a mark to be detected when the workpiece 10 and the laser processing apparatus 1 are aligned. As the key pattern P, for example, a characteristic part of a circuit in the device 13 is used. In the example illustrated in FIG. 3, the key pattern P is a cross-shaped mark that is parallel to the planned dividing lines Lx and the planned dividing lines Ly and intersects with each other. The key pattern P is present at the same position in each device 13, and if the key patterns P formed in the devices 13 disposed in the same row are connected by a line, the line is parallel to the planned dividing lines Lx and Ly in both the X-axis direction and the Y-axis direction.

Returning to FIG. 1, the configuration of the laser processing apparatus 1 will be described. The laser processing apparatus 1 includes, as main components, a holding table 20, the laser irradiation unit 30, a moving unit 40, an imaging unit 50, a display unit 60, and a control unit 100.

### (Holding Table)

The holding table 20 holds the workpiece 10 on a holding surface 21. The holding surface 21 has a disk shape and is made of porous ceramic or the like. In the embodiment, the holding surface 21 is a plane parallel to a horizontal direction. The holding surface 21 is connected to, for example, a vacuum suction source via a vacuum suction path (not illustrated). The holding table 20 holds the workpiece 10 placed on the holding surface 21 by suction. Around the holding table 20, a plurality of clamps 22 for clamping the annular frame 14 that supports the workpiece 10 are disposed.

The holding table 20 is rotated about an axis parallel to the Z-axis direction by a rotation unit 23. The rotation unit 23 is supported by an X-axis direction moving plate 24, and is moved in the X-axis direction together with the holding table 20 by the moving unit 40 (specifically, a processing feed unit 41 to be described later) via the X-axis direction moving plate 24. The rotation unit 23 and the holding table 20 are moved in the Y-axis direction by the moving unit 40 (specifically, an indexing feed unit 42 to be described later) via a Y-axis direction moving plate 25.

### (Laser Irradiation Unit)

The laser irradiation unit 30 is a unit that irradiates the workpiece 10 held on the holding surface 21 of the holding table 20 with a laser beam, and is supported by a column portion 3 erected from an apparatus body 2 of the laser processing apparatus 1. The laser irradiation unit 30 is capable of emitting a pulsed laser beam of a predetermined wavelength that is transparent or absorbent to the workpiece 10 and the tape 15, and emits a transparent laser beam in an embodiment in which a modified layer is formed. Specifically, the laser irradiation unit 30 irradiates the workpiece 10 with a laser beam along the planned dividing lines L to form modified layers 16 (see, for example, FIG. 8) inside the workpiece 10.

The laser irradiation unit 30 includes a condenser 31 that irradiates a desired position inside the workpiece 10 with the laser beam. The condenser 31 is a condenser lens that condenses the laser beam onto the workpiece 10 held on the holding table 20 and irradiates the workpiece 10 with the laser beam. A focal point of the laser beam condensed by the condenser 31 is positioned inside the workpiece 10. Although the back surface of the workpiece 10 is held on the holding table 20 and the front surface 11 is irradiated with the laser beam in the embodiment, the front surface 11 may be held on the holding table 20 and the back surface may be irradiated with the laser beam.

Then, the laser irradiation unit 30 forms the modified layers 16 along the planned dividing lines L by irradiating the workpiece 10 with the laser beam along the planned dividing lines L while relatively moving the focal point of the laser beam and the workpiece 10.

### (Moving Unit)

The moving unit 40 is a unit that moves the focal point of the laser beam in the laser irradiation unit 30 and the imaging unit 50 relative to the workpiece 10 held on the holding table 20. The moving unit 40 includes the processing feed unit 41 and the indexing feed unit 42.

The processing feed unit 41 is a unit that relatively moves the holding table 20 and the focal point of the laser irradiation unit 30 in the X-axis direction, which is a processing feed direction. The processing feed unit 41 is installed on the apparatus body 2 of the laser processing apparatus 1, supports the X-axis direction moving plate 24 in the X-axis direction in a movable manner, and moves the holding table 20 in the X-axis direction via, for example, the X-axis direction moving plate 24.

The indexing feed unit 42 is a unit that relatively moves the holding table 20 and the focal point of the laser irradiation unit 30 in the Y-axis direction, which is an indexing feed direction. The indexing feed unit 42 is installed on the apparatus body 2 of the laser processing apparatus 1, supports the Y-axis direction moving plate 25 in the Y-axis direction in a movable manner, and moves the holding table 20 in the Y-axis direction via, for example, the Y-axis direction moving plate 25 and the X-axis direction moving plate 24.

The processing feed unit 41 and the indexing feed unit 42 each include a ball screw, a pulse motor, and a guide rail (none of which are illustrated). The ball screw is rotatable about an axis. The pulse motor rotates the ball screw about the axis thereof. The guide rail of the processing feed unit 41 supports the X-axis direction moving plate 24 in the X-axis direction in a movable manner. The guide rail of the processing feed unit 41 is fixed to the Y-axis direction moving plate 25. The guide rail of the indexing feed unit 42 supports the Y-axis direction moving plate 25 in the Y-axis direction in a movable manner. The guide rail of the indexing feed unit 42 is fixed to the apparatus body 2.

### (Imaging Unit)

The imaging unit 50 is provided to face the workpiece 10 held on the holding table 20 in the Z-axis direction, and captures an image the workpiece 10. For example, the imaging unit 50 captures images of each of the planned dividing lines L, each of the streets 12, each of the key patterns P formed on each of the devices 13, or the like of the wafer, which is the workpiece 10. For example, the imaging unit 50 is fixed so as to be adjacent to the condenser 31 of the laser irradiation unit 30, and is moved by the moving unit 40 relative to the workpiece 10 held on the holding table 20 together with the laser irradiation unit 30.

The imaging unit 50 includes a microscope part and an imaging part (not illustrated), and the imaging part captures an image of the workpiece 10 imaged by the microscope part. An imaging element includes, for example, a charge-coupled device (CCD) imaging element or a complementary metal oxide semiconductor (CMOS) imaging element. The imaging unit 50 acquires, for example, an image for aligning the workpiece 10 and the laser irradiation unit 30, and outputs the image as image data to the control unit 100. The imaging unit 50 may be, for example, an infrared rays (IR) camera using infrared rays transmitted through the workpiece 10. The imaging unit 50 is an example of an “acquisition unit” of the present disclosure.

### (Display Unit)

The display unit 60 is, for example, a display apparatus including a touch panel display. The display unit 60 displays various types of information such as a processing condition setting screen and a state of the workpiece 10 imaged by the imaging unit 50 (for example, a processing state of the workpiece 10, the street 12, the key pattern P, and the planned dividing line L). The display unit 60 includes an input unit capable of receiving various operations such as registration of processing information by an operator. The display unit 60 may further include a notification unit that notifies the operator of the laser processing apparatus 1 of predetermined information by emitting sound or light.

### (Control Unit)

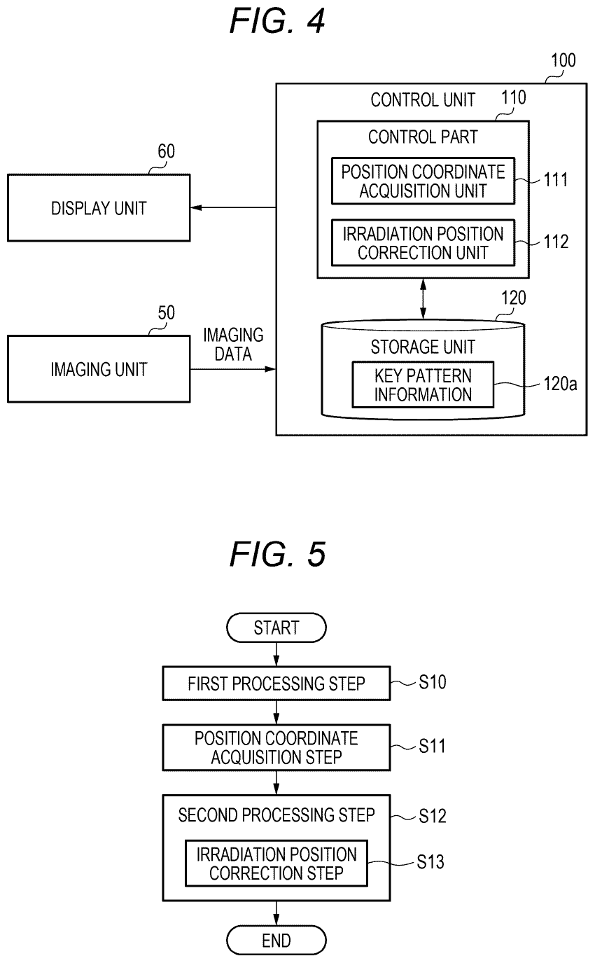

The control unit 100 controls each of the components of the laser processing apparatus 1 described above to cause the laser processing apparatus 1 to perform various processes on the workpiece 10. FIG. 4 illustrates a configuration example including the control unit 100 and configurations of units that input and output data between the control unit 100 and the outside. The control unit 100 is a computer including a control part 110 that performs various calculations, a storage unit 120 having a storage medium, and an input and output interface (not illustrated) that controls input and output of data between the inside and outside of the control unit 100. The control part 110 includes, for example, a microprocessor such as a central processing unit (CPU). The storage unit 120 includes a memory such as a hard disk drive (HDD), a read only memory (ROM), or a random access memory (RAM). The control part 110 performs various calculations based on a predetermined program stored in the storage unit 120. The control part 110 outputs, according to a calculation result, various control signals to the components described above via the input and output interface, and controls the laser processing apparatus 1.

The storage unit 120 stores, for example, key pattern information 120a which is information of the key pattern P formed in the device 13 described above. The key pattern information 120a stores, for example, information such as a shape (cross shape in the embodiment) of the key pattern P preset by an operator or the like, position coordinates of the key pattern P formed on each device 13, and a reference distance D from the key pattern P to the planned dividing line L. The position coordinates may be, for example, XY coordinates such as “X1, Y1”, “X2, Y2”, “X3, Y3”, and the like. As illustrated in FIG. 3, the reference distance D is, for example, a distance obtained by drawing a perpendicular line to the planned dividing line L from an intersecting point of the cross-shaped key pattern P of the embodiment. Before processing by the laser processing apparatus 1, assuming that the key pattern P is formed at the same position on each device 13, the reference distance D from each key pattern P to the planned dividing line Lis substantially the same. In addition, the key pattern information 120a may store other information such as a distance between adjacent planned dividing lines (not illustrated).

The storage unit 120 stores the image data of the workpiece 10 imaged by the imaging unit 50. The image data includes, for example, images of the key pattern P, the street 12, the planned dividing line L, and the like. The image data is output from the imaging unit 50 to the control unit 100 and stored in the storage unit 120. The image data captured by the imaging unit 50 and the above key pattern information 120a can be used as parameters in the processing of the control part 110 to be described later. Detailed processing will be described later in a device chip production method.

The control part 110 executes various programs stored in the storage unit 120. In the laser processing apparatus 1, as described above, the modified layers 16 are formed along the streets 12 of the workpiece 10 when producing a device chip. Here, the modified layers 16 will be described. Each of the modified layers 16 refers to a region in which density, refractive index, mechanical strength, or other physical properties are different from those of the surroundings. The modified layer 16 is, for example, a crack region, a dielectric breakdown region, a refractive index change region, or a mixture of these regions. That is, the portion where the modified layer 16 is formed has lower mechanical strength and the like than other portions of the workpiece 10.

When the mechanical strength is reduced as described above, the workpiece 10 may expand in a direction orthogonal to a direction in which the streets 12 extend, and the streets 12 that have not been processed (that is, the streets 12 to be processed) may be deformed to be curved. In particular, with the miniaturization of devices in recent years, the number of lines processed on the workpiece 10 has increased, and the streets 12 have become denser, making this type of phenomenon more likely to occur. In such a case, if the workpiece 10 is irradiated with a laser beam along the remaining planned dividing lines L to be processed, the devices 13 and the like may be linearly irradiated with the laser beam, which not only leads to damage to a product, but may also cause defective division and the like of the workpiece 10 as no appropriate modified layers 16 are formed inside the wafer, which is the workpiece 10. Therefore, in the embodiment, a program is executed to reduce the damage to the devices 13 due to the curvature of the streets 12 and the defective division of the wafer, which is the workpiece 10.

The control part 110 includes a position coordinate acquisition unit 111 and an irradiation position correction unit 112 as functional units implemented by executing the program. In the following description, the treatments performed by the position coordinate acquisition unit 111 and the irradiation position correction unit 112 are treatments realized by the control part 110.

The position coordinate acquisition unit 111 acquires the position coordinates of the key pattern P captured by the imaging unit 50. That is, the position coordinate acquisition unit 111 acquires the image data output from the imaging unit 50 to the control unit 100 with reference to the storage unit 120, and acquires the key pattern P of the workpiece 10 included in the captured image from the image data. In addition, the storage unit 120 may store the position coordinates of the key pattern P without storing the image data. In such a case, the position coordinate acquisition unit 111 acquires the position coordinate of the key pattern P with reference to the storage unit 120.

The irradiation position correction unit 112 corrects a predetermined planned dividing line L, based on the position coordinates of the key pattern P acquired by the position coordinate acquisition unit 111, and irradiates the workpiece 10 with a laser beam along the corrected planned dividing line Lc. Detailed processing will be described later in a device chip production method.

### (Device Chip Production Method)

Next, a device chip production method according to the embodiment will be described. FIG. 5 is a flowchart illustrating an example of the device chip production method. The production method includes, as processing steps, a first processing step S10, a position coordinate acquisition step S11, and a second processing step S12. The second processing step S12 includes an irradiation position correction step S13. The processing of each step is executed by the control part 110. The position coordinate acquisition step S11 and the second processing step S12 may be executed in parallel, and in the embodiment, an example in which the position coordinate acquisition step S11 and the second processing step S12 are executed in parallel will be described. An example of separately (that is, sequentially) executing the position coordinate acquisition step S11 and the second processing step S12 will be described later in a modification.

In the device chip production method according to the embodiment, before executing the first processing step S10, the control part 110 conveys the workpiece 10 onto the holding table 20 by a conveying unit (not illustrated) or the like and holds the workpiece 10 on the holding surface 21 of the holding table 20.

In the first processing step S10, the control part 110 forms the modified layer 16 inside the workpiece 10 by irradiating the workpiece 10 with a laser beam having a wavelength that transmits through the workpiece 10 along a first planned dividing line. Here, the first planned dividing line may be either the planned dividing line Lx extending in the X-axis direction or the planned dividing line Ly extending in the Y-axis direction, but in the embodiment, the first planned dividing line is the planned dividing line Lx extending in the X-axis direction.

The first processing step S10 will be specifically described. The control part 110 captures an image of any street 12 among the plurality of streets 12 formed in the X-axis direction, and rotates the holding table 20 using the captured image such that, for example, the street 12 of the workpiece 10 is parallel to moving directions of the laser irradiation unit 30 and the imaging unit 50 in the X-axis direction. Then, since the planned dividing line Lx extending in the X-axis direction is formed in advance along a center of the street 12, the control part 110 controls the laser irradiation unit 30 to perform the processing of irradiating the workpiece 10 with a laser beam along the planned dividing line Lx to form the modified layer 16 inside the workpiece 10. For example, as illustrated in FIG. 3, the processing is performed sequentially from the planned dividing line Lx₁ formed on an outer side of the workpiece 10.

In the first processing step S10, the processing of forming the modified layer 16 may be performed on any number (for example, one, three, five, or ten) of planned dividing lines Lx set by an operator or the like among the plurality of planned dividing lines Lx extending in the X-axis direction. The number is determined, for example, in consideration of deformation (curvature) of the street 12 caused by forming the modified layer 16. That is, the number of lines to be processed is determined taking into consideration circumstances such as the need to correct the lines to be processed along which the workpiece 10 is irradiated with the laser beam, since continuing processing along the predetermined planned dividing line Lx may result in damage to the device 13 and the like. The number of lines to be processed in the first processing step S10 may be determined in advance by, for example, an experiment of acquiring the degree of deformation of the street 12 due to the formation of the modified layer 16. Since the degree of deformation of the street 12 may vary depending on the material or the like of the workpiece 10, any number of streets 12 to be processed in the first processing step S10 may be determined depending on the material or the like of the workpiece 10. In the embodiment, in the first processing step S10, as an example, the processing is performed along three planned dividing lines Lx₁, Lx₂, and Lx₃.

In the position coordinate acquisition step S11, the control part 110 acquires the position coordinates of the key pattern P formed in a predetermined region of the workpiece 10 along an extending direction of an adjacent planned dividing line adjacent to the planned dividing line Lx processed in the first processing step S10. The adjacent planned dividing line refers to a planned dividing line Lx that has not yet been processed and is to be processed, among the planned dividing lines adjacent to the planned dividing line Lx (here, planned dividing lines Lx₁, Lx₂, and Lx₃) processed in the first processing step S10. For example, the adjacent planned dividing line is a planned dividing line Lx₄ adjacent to the planned dividing line Lx₃.

More specifically, in the position coordinate acquisition step S11, the control part 110 controls the imaging unit 50 to capture an image of a region not irradiated with the laser beam. For example, the imaging unit 50 captures an image of the key pattern P formed on the device 13 of the workpiece 10 in the extending direction (that is, the X-axis direction) of the planned dividing line Lx to be processed next. That is, the control part 110 moves the holding table 20 in the X-axis direction by the moving unit 40, and acquires an image of the key pattern P on the planned dividing line Lx to be processed next by the imaging unit 50. The captured image is output to the control unit 100, and the control part 110 acquires the position coordinates of the key pattern P from the image.

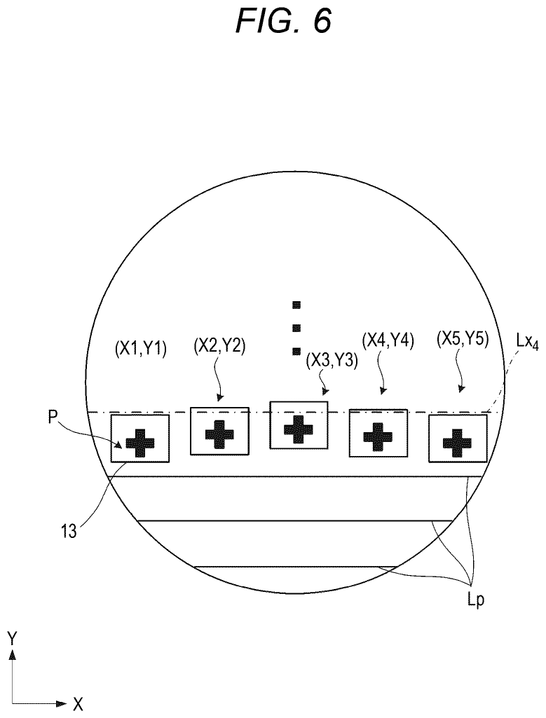

FIG. 6 is a diagram illustrating an example of the acquired image of the key pattern P. The image in FIG. 6 shows a part of the entire workpiece 10, and for convenience of description, the image shows a part of the key patterns p formed on the devices 13 in the extending direction of the planned dividing line Lx₄ and lines Lp that have already been processed. Here, the processed lines Lp are lines processed by the laser irradiation unit 30 along the planned dividing lines Lx₁, Lx₂, and Lx₃. Since the modified layer 16 formed by the processed lines Lp is formed inside the workpiece 10, it is usually impossible to determine whether the processed lines Lp have been processed unless cracks or the like have occurred, but in the example illustrated in FIG. 6, the processed lines Lp are indicated by solid lines for convenience of describing that the processed lines Lp has been processed.

In the position coordinate acquisition step S11, the control part 110 acquires a plurality of position coordinates of a plurality of key patterns P at a predetermined interval along the planned dividing line Lx to be processed next. This processing is for acquiring the “corrected planned dividing line Lc” to be acquired in the second processing step S12 to be described later, which is a line acquired by correcting the predetermined planned dividing line Lx. Therefore, in terms of acquiring the corrected planned dividing line Lc, at least two key patterns P are necessary, but in order to acquire a line with high accuracy, it is better to have a larger number of key patterns P. In the embodiment, since it is assumed that the street 12 is curved, it is preferable to acquire the position coordinates of three or more key patterns P so as to acquire the corrected planned dividing line Lc that follows the curvature of the street 12.

As can be seen from FIG. 6, the positions of the key patterns P on the devices 13 are different. In other words, distances from the planned dividing line Lx₄ to centers of the key patterns P vary, and the planned dividing line Lx4 partially overlap the devices 13. Therefore, if the processing is continued along such a planned dividing line Lx₄, the devices 13 may be damaged. Therefore, in the second processing step S12, the processing is performed after the planned dividing line Lx to be processed is corrected.

In the second processing step S12, the control part 110 corrects the planned dividing line Lx to be processed (that is, the planned dividing line Lx₄ which is an example of the adjacent planned dividing line described above), based on the position coordinates of the key patterns P acquired in the position coordinate acquisition step S11, and irradiates the workpiece 10 with a laser beam along the corrected planned dividing line Lc to form the modified layer 16 inside the workpiece 10.

The second processing step S12 includes the irradiation position correction step S13. In the second processing step S12, after the processing of calculating the “corrected planned dividing line Lc”, which is a line acquired by correcting the planned dividing line Lx in the irradiation position correction step S13, the processing of forming the modified layer 16 is performed.

Specifically, in the irradiation position correction step S13, the control part 110 acquires a positional deviation amount between the position coordinates of the plurality of key patterns P acquired in the position coordinate acquisition step S11 and the position coordinates of the key patterns P before processing stored in the storage unit 120. That is, the control part 110 refers to the storage unit 120, specifies the position coordinates of the key pattern P corresponding to the plurality of acquired position coordinates of each of the key patterns P, and acquires a positional deviation amount in the Y-axis direction by comparing the position coordinates of the key pattern P with the position coordinates of the key pattern P formed in each device 13.

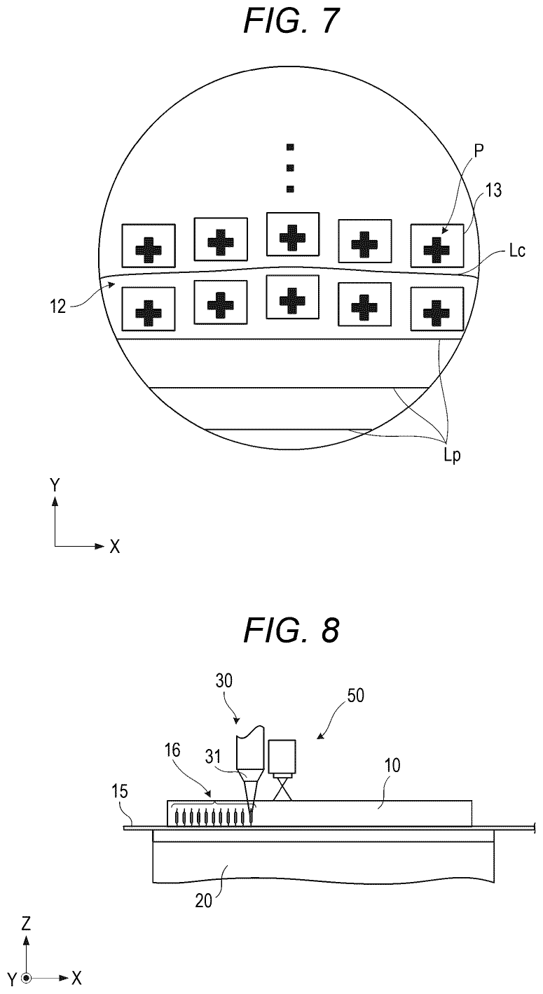

Then, the control part 110 offsets the planned dividing line Lx to be processed by the acquired positional deviation amount to calculate a trajectory of the planned dividing line Lc to be corrected. FIG. 7 is a diagram for explaining an example of the corrected planned dividing line Lc. As can be seen from FIG. 7, the corrected planned dividing line Lc has a curved shape. That is, by correcting the predetermined planned dividing line Lx₄ based on the position coordinates of the key pattern P in which positional deviation occurs in the Y-axis direction, the corrected planned dividing line Lc becomes a line that follows the shape of the curved street 12.

A method for calculating the trajectory of the corrected planned dividing line Lc is not limited thereto as long as the trajectory can be calculated using the position coordinates of the key pattern P. For example, the reference distance D from the key pattern P to the planned dividing line Lx is stored in advance in the storage unit 120. Therefore, for example, the control part 110 may obtain each point at which a distance from a center (a point at which the cross-shaped key pattern P intersects) of the acquired key pattern P to the predetermined planned dividing line Lx is the reference distance D, and may set a line connecting the points as the trajectory of the corrected planned dividing line Lc. Accordingly, the trajectory follows the curved street 12.

In the second processing step S12, the modified layer 16 is formed inside the workpiece 10 along the “corrected planned dividing lines Lc” calculated in this manner.

FIG. 8 is a diagram for explaining a process in the second processing step S12, and in the example illustrated in FIG. 8, the position coordinate acquisition step S11 described above is executed in parallel with the second processing step S12. That is, while the moving unit 40 moves the holding table 20 in the X-axis direction, the laser irradiation unit 30 forms the modified layer 16 inside the workpiece 10, and the imaging unit 50 captures the key pattern P formed on the device 13. In the example illustrated in FIG. 8, the imaging unit 50 is disposed in the X-axis direction on a forward side (front side) of the laser irradiation unit 30, which advances the processing, but the imaging unit 50 may be disposed on a rear side of the laser irradiation unit 30, for example. Alternatively, the imaging unit 50 may be disposed in front of or behind the laser irradiation unit 30.

As described above, by executing the position coordinate acquisition step S11 while executing the second processing step S12, for example, the planned dividing line Lx currently being processed can be irradiated with a laser beam, and the modified layer 16 can be formed along the corrected planned dividing line Lc while correcting the planned dividing line Lx in real time.

In the second processing step S12, instead of irradiating the planned dividing line Lx (for example, the planned dividing line Lx₄) that is currently being processed with a laser beam based on the acquired position coordinates of the key pattern p, for example, after the planned dividing line Lx₄ that is currently being processed is processed, an adjacent planned dividing line Lx (for example, a planned dividing line Lx₅ illustrated in FIG. 3) that has not been irradiated with the laser beam may be further irradiated with the laser beam, based on the acquired position coordinates of the key pattern p. In other words, the acquisition of the position coordinates of the key pattern P is performed in parallel with the second processing step S12, but the processing based on the acquired position coordinates of the key pattern P may be performed on a planned dividing line Lx different from the planned dividing line Lx currently being processed. The planned dividing line Lx₄ is an example of a “second planned dividing line” in the present disclosure, and the planned dividing line Lx₅ is an example of a “third planned dividing line” in the present disclosure.

The control part 110 performs the series of processes illustrated in FIG. 5 at intervals of a predetermined number of streets (planned dividing lines Lx) in consideration of deformation of the street 12. When the control part 110 has completed the processing for all the planned dividing lines Lx in the X-axis direction, the control part 110 subsequently performs the same processing on the planned dividing lines Ly in the Y-axis direction intersecting the planned dividing lines Lx in the X-axis direction. For example, the processing is performed in the order of planned dividing lines Ly₁, Ly₂, and Ly₃ illustrated in FIG. 3.

At this time, as described above, in the position coordinate acquisition step S11, the position coordinates of the plurality of key patterns P are acquired at a predetermined interval along the planned dividing line Ly to be processed next, and the interval may be different from the interval acquired during the processing in the X-axis direction. This is because the degree of deformation of the street 12 may be different between the X-axis direction and the Y-axis direction, and it is preferable to acquire the position coordinates of the key pattern P at an interval corresponding to each condition. That is, in the position coordinate acquisition step S11, when acquiring the position coordinates of the key pattern P along the planned dividing line Ly, the control part 110 may acquire the position coordinates of the key pattern P at an interval different from the interval between the position coordinates of the key pattern P acquired along the planned dividing line Lx extending in the X-axis direction.

The planned dividing line Lx is an example of a “first direction planned dividing line extending in a first direction” in the present disclosure, and the planned dividing line Ly is an example of a “second direction planned dividing line extending in a second direction” in the present disclosure. The interval between the position coordinates of the key patterns P acquired along the planned dividing line Lx is an example of a “first interval”, and the interval between the position coordinates of the key patterns P acquired along the planned dividing line Ly is an example of a “second interval”.

On the other hand, in a case where the processing is performed on the planned dividing line Ly after the processing on the planned dividing line Lx, the interval (that is, the second interval) between the position coordinates along the planned dividing line Ly set in advance may increase due to the processing of forming the modified layer 16 in the X-axis direction that has already been performed. Specifically, since the modified layer 16 has already been formed in the X-axis direction, the distance between the key patterns may be greater than before the processing is performed. Therefore, in consideration of such circumstances, it is preferable to acquire the position coordinates of the key pattern P along the planned dividing line Ly. For example, when the control part 110 forms the modified layer 16 along the planned dividing line Ly after forming the modified layer 16 along the planned dividing line Lx, the interval between the position coordinates of the key patterns P acquired along the planned dividing line Ly is set to a “third interval” greater than the second interval described above. That is, the control part 110 acquires the position coordinates of the key pattern P along the planned dividing line Ly in consideration of an increase in the distance between the key patterns. This is based on the position coordinates of the key pattern P at a desired interval.

Since the processing of the other planned dividing lines Ly extending in the Y-axis direction is the same as the processing of the planned dividing lines Lx extending in the X-axis direction, the description thereof will be omitted.

Then, the workpiece 10 on which the modified layer 16 is formed as described above is divided from the modified layer 16 as a starting point by applying an external force in a radial direction to the tape 15 by, for example, a dedicated apparatus (not illustrated). Accordingly, the plurality of devices 13 formed on the workpiece 10 are individually divided, and a plurality of device chips are produced.

As described above, in the embodiment, the predetermined planned dividing line Lis corrected based on the position coordinates of the key pattern P, and an irradiation position of the laser beam with respect to the workpiece 10 is adjusted along the corrected planned dividing line Lc. Accordingly, for example, even if deformation such as curvature of the street 12 occurs in the process of forming the modified layer 16 inside the workpiece 10, the planned dividing line Lis corrected based on the position coordinates of the key pattern P, and the workpiece 10 is irradiated with a laser beam along the corrected planned dividing line Lc. As a result, it is possible to perform irradiation with a laser beam following the curved street 12, it is possible to prevent the device 13 from being linearly irradiated with a laser beam, and it is possible to reduce or avoid damage to the device 13 and to reduce or avoid a wafer, which is the workpiece 10, from being left undivided.

As described above, in the embodiment, for example, after the first processing step S10 is executed, the position coordinate acquisition step S11 is performed while executing the second processing step S12, and a planned dividing line being processed is irradiated with a laser beam, based on the position coordinates of the key pattern P acquired in the position coordinate acquisition step S11. Accordingly, the second processing step S12 can be performed following the key pattern P acquired in the position coordinate acquisition step S11, the planned dividing line L can be corrected in real time, and in the second processing step S12, the workpiece 10 can be irradiated with a laser beam along the corrected planned dividing line Lc.

In the embodiment, for example, after the first processing step S10 is executed, the position coordinate acquisition step S11 is performed while executing the second processing step S12, and an adjacent planned dividing line different from the planned dividing line currently being processed is irradiated with a laser beam, based on the position coordinates of the key pattern P acquired in the position coordinate acquisition step S11. Accordingly, for example, as compared with the case where the processing is performed while correcting the planned dividing line L in real time as described above, a control load may be reduced, and the accuracy of the correction and processing of the planned dividing line L may be improved.

In the embodiment, in the position coordinate acquisition step S11, a plurality of position coordinates of the key patterns P are acquired along the planned dividing line L to be processed. Therefore, a trajectory of the planned dividing line Lc to be corrected can be calculated based on the acquired position coordinates of the plurality of key patterns P. In particular, the greater the number of position coordinates of the acquired key patterns P, the more accurate the trajectory can be calculated, and therefore the accuracy of correction of the planned dividing line can be improved.

In the embodiment, for example, intervals at which the position coordinates of the key patterns P on the planned dividing line Lx extending in the X-axis direction and the planned dividing line Ly extending in the Y-axis direction are acquired are different from each other. That is, conditions for acquiring the position coordinates of the key patterns P are independent of each other. In other words, since deformation such as curvature of the street 12 may be different between the X-axis direction and the Y-axis direction, it is possible to more accurately perform processing along the shape of the street 12 by acquiring the position coordinates of the key patterns P in each of the axial directions, correcting the planned dividing line based on the position coordinates, and performing laser irradiation.

On the other hand, in a case where the processing is performed on the planned dividing line Ly after the processing on the planned dividing line Lx, the interval between the position coordinates along the planned dividing line Ly set in advance may increase due to the processing of forming the modified layer 16 in the X-axis direction that has already been performed, and in the embodiment described above, such circumstances are considered. That is, the interval of the position coordinates of the key patterns P acquired along the planned dividing line Ly is set to a third interval greater than the preset second interval. Accordingly, for example, even in a case where the device interval is increased due to the processing along the planned dividing lines Lx, by acquiring the position coordinates of the key pattern P along the planned dividing line Ly at every third interval greater than the preset second interval, the processing along the planned dividing line Ly is based on the position coordinates of the key pattern P at a desired device interval.

### Modifications

Next, modifications will be described. In the embodiment described above, the processing of the position coordinate acquisition step S11 is performed in parallel with the processing of the second processing step S12, but the processing of the position coordinate acquisition step S11 may be executed separately from the processing of the second processing step S12. In this case, after the first processing step S10 is executed, the processing is performed in the order of the position coordinate acquisition step S11 and the second processing step S12.

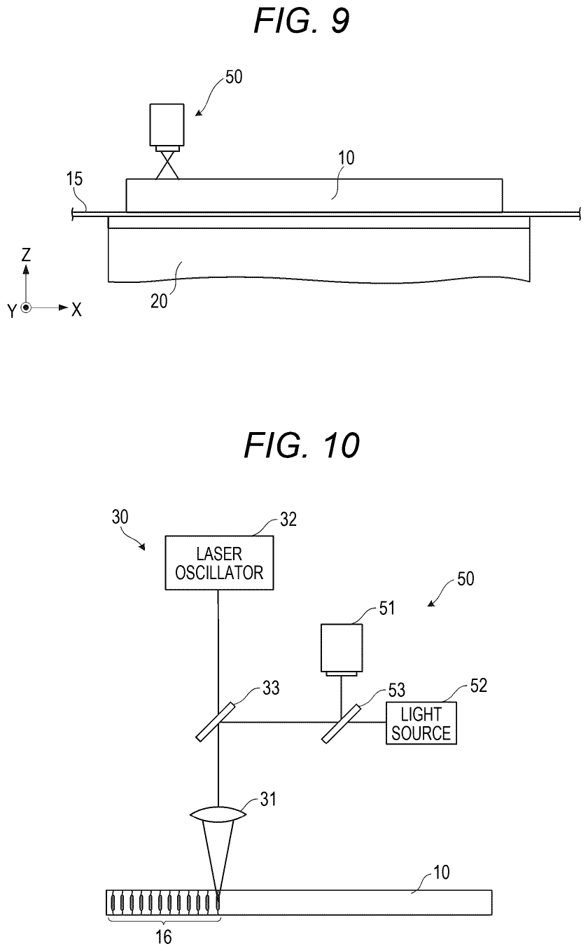

FIG. 9 is a diagram illustrating an example of a modification of the processing of the position coordinate acquisition step S11, and in the example illustrated in FIG. 9, since the second processing step S12 is not performed in parallel, only the imaging unit 50 is moved relative to the holding table 20.

As described above, by performing the processing of the position coordinate acquisition step S11 as separate processing instead of performing the processing of the position coordinate acquisition step S11 in parallel with the second processing step S12, for example, as compared with a case where the processing of acquiring the key pattern P and the processing of irradiating the workpiece 10 with a laser beam are simultaneously executed, the accuracy of either processing may be improved, and in this case, processing can be performed more accurately along deformation of the street 12.

In the embodiment described above, the laser irradiation unit 30 is disposed so as to face an object to be processed on the workpiece 10 in the Z-axis direction, and the imaging unit 50 is disposed adjacent to the laser irradiation unit 30. Therefore, the laser irradiation unit 30 and the imaging unit 50 are disposed on different axes. On the other hand, since an object to be irradiated with a laser beam by the laser irradiation unit 30 and an object to be imaged by the imaging unit 50 are substantially the same, such as the planned dividing line L, the street 12, and the like, a processing position in the laser irradiation unit 30 and an imaging position in the imaging unit 50 are preferably coaxial. Therefore, FIG. 10 schematically illustrates an example in which the processing position in the laser irradiation unit 30 and the imaging position in the imaging unit 50 are substantially coaxial.

In a modification illustrated in FIG. 10, among the components constituting the laser processing apparatus 1 described above, the laser irradiation unit 30, the imaging unit 50, and the workpiece 10 are illustrated.

As illustrated in FIG. 10, the laser irradiation unit 30 includes a laser oscillator 32 that emits a laser beam, a dichroic mirror 33, and a condenser 31. The imaging unit 50 includes a camera 51, a light source 52, and a dichroic mirror 53.

In the laser irradiation unit 30, the laser beam emitted from the laser oscillator 32 passes through the dichroic mirror 33 and is directed to the condenser 31, and the modified layer 16 is formed inside the workpiece 10. In the imaging unit 50, illumination light emitted from the light source 52 is reflected by the dichroic mirror 33 and directed to an imaging region via the condenser 31, and the incident light from the imaging region is directed to the camera 51 via the condenser 31. The camera 51 can capture an image of the imaging region based on the incident light from the imaging region. The imaging region is the planned dividing line L, the street 12, or the like on the workpiece 10.

As described above, in the modification illustrated in FIG. 10, it is possible to emit the laser beam in the laser irradiation unit 30 and the illumination light for imaging in the imaging unit 50 coaxially. Accordingly, since there is no deviation between the processing position of the workpiece 10 in the laser irradiation unit 30 and the imaging position in the imaging unit 50, it is possible to more accurately correct the planned dividing line L and perform the processing along the corrected planned dividing line Lc.

The modification illustrated in FIG. 10 is not limited to the example of FIG. 10 as long as the laser beam of the laser irradiation unit 30 and the illumination light in the imaging unit 50 are coaxial.

Although the embodiments of the present disclosure have been described above with reference to the accompanying drawings, it is needless to say that the present disclosure is not limited to the embodiments. It is obvious that those skilled in the art may come up with various changes or modifications within the scope of the claims, and it is understood that these naturally fall within the technical scope of the present disclosure. In addition, components in the embodiments described above may be freely combined without departing from the gist of the disclosure.

In the embodiment described above, the processing is performed from the planned dividing line Lx extending in the X-axis direction among the planned dividing lines L intersecting each other, but the processing may be performed from the planned dividing line Ly extending in the Y-axis direction.

In the embodiment described above, the moving unit 40 is configured to move the holding table 20 to move a focal point of a laser beam relative to the workpiece 10, but for example, the laser irradiation unit 30 may be scanned to move the focal point of the laser beam relative to the workpiece 10. That is, the relative movement may be performed by scanning using a laser beam. When scanning using a laser beam, for example, a known galvanometer scanner, an acousto optic deflector (AOD), an optical modulator, or the like may be used.

For example, the laser processing apparatus 1 described above may be separated into a plurality of apparatuses. For example, at least a part of the imaging unit 50, the display unit 60, the control part 110, and the storage unit 120 included in the laser processing apparatus 1 described above may be separate apparatuses. A processing system may include a plurality of apparatuses. For example, when the imaging unit 50 is configured separately from the laser processing apparatus 1, image data captured by the imaging unit 50 is output to the control unit 100 and stored in the storage unit 120, and the control part 110 refers to the storage unit 120 to acquire the position coordinates of the key pattern P formed on the device 13. An apparatus or system that is separated into a plurality of apparatuses is not limited thereto.

For example, in the control unit 100 described above, the position coordinate acquisition unit 111 and the irradiation position correction unit 112 constituting the control part 110 may be separated into a plurality of apparatuses. For example, a part of functions of the position coordinate acquisition unit 111 and the irradiation position correction unit 112 may be implemented by a server or the like.

The production method described in the above embodiment can be implemented by executing a control program prepared in advance by a computer. The control program is recorded in a computer-readable storage medium and executed by being read from the storage medium. The control program may be provided in a form stored in a non-transitory storage medium such as a flash memory, or may be provided via a network such as the Internet. The computer that executes the control program may be included in a processing device, may be included in an electronic device such as a smartphone, a tablet terminal, or a personal computer capable of communicating with the processing device, or may be included in a server device capable of communicating with the processing device and the electronic device.

The present specification describes at least following matters. The components in parentheses correspond to those in the embodiment described above, but are not limited thereto.

(1) A device chip production method for producing a device chip by dividing a workpiece (workpiece 10) in which a plurality of devices (devices 13) are formed in regions partitioned by a plurality of planned dividing lines (planned dividing lines L) along the planned dividing lines, the method including:
a first processing step (first processing step S10) of forming a modified layer (modified layer 16) inside the workpiece by irradiating the workpiece with a laser beam having a wavelength that transmits through the workpiece along a first planned dividing line (planned dividing line Lx₃);
a second processing step (second processing step S12) of forming a modified layer inside the workpiece by irradiating the workpiece with the laser beam along an adjacent planned dividing line (planned dividing line Lx₄) adjacent to the first planned dividing line processed in the first processing step, after the first processing step is performed; and
a position coordinate acquisition step (position coordinate acquisition step S11) of acquiring a position coordinate of a key pattern (key pattern P) formed in a predetermined region of the workpiece along an extending direction of the adjacent planned dividing line, after the first processing step is performed, in which
in the second processing step, the adjacent planned dividing line is corrected based on the position coordinate of the key pattern acquired in the position coordinate acquisition step, and the workpiece is irradiated with the laser beam along the corrected adjacent planned dividing line (corrected planned dividing line Lc).

According to (1), for example, it is possible to perform irradiation with a laser beam following a deformed street such as a curved street, it is possible to prevent the devices from being linearly irradiated with a laser beam, and it is possible to reduce or avoid damage to the device and to reduce or avoid the workpiece from being left undivided.

(2) The device chip production method according to (1), in which
while executing the second processing step, the position coordinate of the key pattern is acquired by capturing an image of a region not irradiated with the laser beam in the position coordinate acquisition step, and
in the second processing step, the adjacent planned dividing line being processed is irradiated with the laser beam based on the acquired position coordinate of the key pattern.

According to (2), for example, the second processing step can be executed following the key pattern acquired in the position coordinate acquisition step, the planned dividing line can be corrected in real time, and in the second processing step, the workpiece can be irradiated with the laser beam along the corrected planned dividing line.

(3) The device chip production method according to (1), in which
the adjacent planned dividing line includes at least a second planned dividing line (planned dividing line Lx₄) and a third planned dividing line (planned dividing line Lx₅),
in the second processing step, the position coordinate acquisition step acquires the position coordinate of the key pattern by capturing an image of a region not irradiated with the laser beam while processing the second planned dividing line, and
after the processing along the second planned dividing line, the second processing step irradiates the third planned dividing line with the laser beam based on the acquired position coordinate of the key pattern.

According to (3), for example, as compared with the case where the processing is performed while correcting the planned dividing line in real time as described above, a control load may be reduced, and the accuracy of the correction of the planned dividing line and the processing associated therewith may be improved.

(4) The device chip production method according to (1), in which
the position coordinate acquisition step is performed after the first processing step is executed and before the second processing step is executed.

According to (4), the position coordinate acquisition step and the second processing step are each performed as separate processing. Therefore, for example, as compared with a case where the position coordinate acquisition step and the second processing step are executed in parallel, the accuracy of either processing may be improved, and in this case, processing can be performed more accurately along deformation of the street.

(5) The device chip production method according to (1), in which
the position coordinate acquisition step acquires position coordinates of a plurality of the key patterns at every predetermined first interval along the adjacent planned dividing line.

According to (5), for example, a trajectory of the planned dividing line to be corrected can be calculated based on the acquired position coordinates of the plurality of key patterns.

(6) The device chip production method according to (5), in which
the adjacent planned dividing line includes a first direction planned dividing line (planned dividing line Lx) extending in a first direction and a second direction planned dividing line (planned dividing line Ly) extending in a second direction intersecting the first direction, and
the position coordinate acquisition step
   acquires position coordinates of a plurality of the key patterns at every first interval when acquiring the position coordinates of the plurality of the key patterns along the first direction planned dividing line, and
   acquires position coordinates of a plurality of the key patterns at every second interval different from the first interval when acquiring the position coordinates of the plurality of the key patterns along the second direction planned dividing line.

According to (6), the intervals for acquiring the position coordinate of the key pattern between the first direction planned dividing line extending in the first direction and the second direction planned dividing line extending in the second direction are different from each other. Accordingly, the position coordinate of the key pattern can be acquired at an interval in consideration of the deformation of the workpiece in each direction, and as a result, the planned dividing line can be corrected more accurately.

(7) The device chip production method according to (5), in which
the adjacent planned dividing line includes a first direction planned dividing line extending in a first direction and a second direction planned dividing line extending in a second direction intersecting the first direction, and
when the modified layer is formed along the first direction planned dividing line and then the modified layer is formed along the second direction planned dividing line, the position coordinate acquisition step
   acquires position coordinates of a plurality of the key patterns at every first interval when acquiring the position coordinates of the plurality of the key patterns along the first direction planned dividing line, and
   acquires the position coordinates of a plurality of the the key patterns at every third interval greater than a predetermined second interval when acquiring the position coordinates of the plurality of the key patterns along the second direction planned dividing line.

According to (7), for example, even in a case where the device interval is increased due to the processing along the first direction planned dividing line, by acquiring the position coordinate of the key pattern along the second direction planned dividing line at every third interval greater than the preset second interval, the processing along the second direction planned dividing line is based on the position coordinate of the key pattern at a desired device interval.

(8) A laser processing apparatus (laser processing apparatus 1) for processing a workpiece (workpiece 10) having a plurality of devices (devices 13) formed in regions partitioned by a plurality of planned dividing lines (planned dividing lines L) by irradiating the workpiece with a laser beam, the laser processing apparatus including:
a holding table (holding table 20) configured to hold the workpiece;
a laser irradiation unit (laser irradiation unit 30) configured to irradiate the workpiece with the laser beam having a wavelength that is transparent to the workpiece to form a modified layer (modified layer 16) inside the workpiece;
a moving unit (moving unit 40) configured to relatively move the workpiece held on the holding table and a focal point of the laser beam;
an acquisition unit (imaging unit 50) configured to acquire a position coordinate of a key pattern (key pattern P) formed in a predetermined region of the workpiece; and
a control unit (control unit 100) configured to control the laser processing apparatus, in which
the control unit includes
   a position coordinate acquisition unit (position coordinate acquisition unit 111) configured to acquire the position coordinate of the key pattern acquired by the acquisition unit, and
   an irradiation position correction unit (irradiation position correction unit 112) configured to correct the planned dividing line based on the acquired position coordinate and irradiate the workpiece with the laser beam along the corrected planned dividing line (corrected planned dividing line Lc).

According to (8), for example, it is possible to perform irradiation with a laser beam following a deformed street such as a curved street, it is possible to prevent the devices from being linearly irradiated with a laser beam, and it is possible to reduce or avoid damage to the device and to reduce or avoid the workpiece from being left undivided.

### REFERENCE SIGNS LIST

1 laser processing apparatus
10 workpiece
13 device
16 modified layer
20 holding table
30 laser irradiation unit
40 moving unit
50 imaging unit (acquisition unit)
100 control unit
111 position coordinate acquisition unit
112 irradiation position correction unit
L planned dividing line
Lc corrected planned dividing line
Lx planned dividing line (first direction planned dividing line)
Ly planned dividing line (second direction planned dividing line)
Lx3 planned dividing line (first planned dividing line)
Lx4 planned dividing line (adjacent planned dividing line, second planned dividing line)
Lx5 planned dividing line (third planned dividing line)
P key pattern
S10 first processing step
S11 position coordinate acquisition step
S12 second processing step

What is claimed is:

1. A device chip production method for producing a device chip by dividing a workpiece in which a plurality of devices are formed in regions partitioned by a plurality of planned dividing lines along the planned dividing lines, the method comprising:
irradiating the workpiece with a laser beam having a wavelength that transmits through the workpiece along a first planned dividing line among the plurality of planned dividing lines to form a modified layer inside the workpiece;
irradiating the workpiece with the laser beam along an adjacent planned dividing line, among the plurality of planned dividing lines, adjacent to the first planned dividing line, after the irradiating of the workpiece with the laser beam along the first planned dividing line is performed, to form a modified layer inside the workpiece; and
acquiring a position coordinate of a key pattern formed in a predetermined region of the workpiece along an extending direction of the adjacent planned dividing line, after the irradiating of the workpiece with the laser beam along the first planned dividing line is performed, wherein
in the irradiating of the workpiece with the laser beam along the adjacent planned dividing line, the adjacent planned dividing line is corrected based on the position coordinate of the key pattern acquired in the acquiring, and the workpiece is irradiated with the laser beam along the corrected adjacent planned dividing line.

2. The device chip production method according to claim 1, wherein
while executing the irradiating of the workpiece with the laser beam along the adjacent planned dividing line, the position coordinate of the key pattern is acquired by capturing an image of a region not irradiated with the laser beam in the acquiring, and
in the irradiating of the workpiece with the laser beam along the adjacent planned dividing line, the adjacent planned dividing line being processed is irradiated with the laser beam based on the acquired position coordinate of the key pattern.

3. The device chip production method according to claim 1, wherein
the adjacent planned dividing line includes at least a second planned dividing line and a third planned dividing line,
in the irradiating of the workpiece with the laser beam along the adjacent planned dividing line, the acquiring acquires the position coordinate of the key pattern by capturing an image of a region not irradiated with the laser beam while processing the second planned dividing line, and
after the processing along the second planned dividing line, the irradiating of the workpiece with the laser beam along the adjacent planned dividing line irradiates the third planned dividing line with the laser beam based on the acquired position coordinate of the key pattern.

4. The device chip production method according to claim 1, wherein
the acquiring is performed after the irradiating of the workpiece with the laser beam along the first planned dividing line is executed and before the irradiating of the workpiece with the laser beam along the adjacent planned dividing line is executed.

5. The device chip production method according to claim 1, wherein
the acquiring acquires position coordinates of a plurality of the key patterns at every predetermined first interval along the adjacent planned dividing line.

6. The device chip production method according to claim 5, wherein
the adjacent planned dividing line includes a first direction planned dividing line extending in a first direction and a second direction planned dividing line extending in a second direction intersecting the first direction, and
the acquiring
acquires position coordinates of a plurality of the key patterns at every first interval when acquiring the position coordinates of the plurality of the key patterns along the first direction planned dividing line, and
acquires position coordinates of a plurality of the key patterns at every second interval different from the first interval when acquiring the position coordinates of the plurality of the key patterns along the second direction planned dividing line.

7. The device chip production method according to claim 5, wherein
the adjacent planned dividing line includes a first direction planned dividing line extending in a first direction and a second direction planned dividing line extending in a second direction intersecting the first direction, and
in a case where the modified layer is formed along the first direction planned dividing line and then the modified layer is formed along the second direction planned dividing line, the acquiring
acquires position coordinates of a plurality of the key patterns at every first interval when acquiring the position coordinates of the plurality of the key patterns along the first direction planned dividing line, and
acquires position coordinates of a plurality of the key patterns at every third interval greater than a predetermined second interval when acquiring the position coordinates of the plurality of the key patterns along the second direction planned dividing line.

8. A laser processing apparatus for processing a workpiece having a plurality of devices formed in regions partitioned by a plurality of planned dividing lines by irradiating the workpiece with a laser beam, the laser processing apparatus comprising:
a holding table configured to hold the workpiece;
a laser irradiation unit configured to irradiate the workpiece with the laser beam having a wavelength that is transparent to the workpiece to form a modified layer inside the workpiece;
a moving unit configured to relatively move the workpiece held on the holding table and a focal point of the laser beam;
an acquisition unit configured to acquire a position coordinate of a key pattern formed in a predetermined region of the workpiece; and
a controller configured to control the laser processing apparatus, wherein
the controller includes
a position coordinate acquisition unit configured to acquire the position coordinate of the key pattern acquired by the acquisition unit, and
an irradiation position correction unit configured to correct the planned dividing line based on the acquired position coordinate and irradiate the workpiece with the laser beam along the corrected planned dividing line.
